(19) United States
(12) Patent Application Publication
(10) Pub. No.: US 2020/0058814 A1
(43) Pub. Date: Feb. 20, 2020

(54) DEVICE AND REALIZATION METHOD OF LUMINESCENT SOLAR CONCENTRATORS BASED ON SILICON NANOSTRUCTURES

(71) Applicants: ALMA MATER STUDIORUM - UNIVERSITÀ DI BOLOGNA, BOLOGNA (IT); CONSIGLIO NAZIONALE DELLE RICERCHE, ROMA (IT)

(72) Inventors: PAOLA CERONI, BOLOGNA (IT); RAFFAELLO MAZZARO, BOLOGNA (IT); GIACOMO BERGAMINI, BOLOGNA (IT); ANTONINO ARRIGO, BOLOGNA (IT); FRANCESCO ROMANO, BOLOGNA (IT); VITTORIO MORANDI, ROMA (IT); MARIACONCETTA CANINO, ROMA (IT)

(21) Appl. No.: 16/487,407

(22) PCT Filed: Feb. 20, 2018
(86) PCT No.: PCT/IT2018/050023

§ 371 Date: Aug. 20, 2019

(30) Foreign Application Priority Data
Feb. 21, 2017 (IT) 102017000018941

(51) Int. Cl. H01L 31/055; H01L 31/054; C09K 11/02; C09K 11/59

(52) U.S. Cl. CPC H01L 31/055; C09K 11/59; C09K 11/02; H01L 31/0547

(57) ABSTRACT

An energy conversion device, particularly electromagnetic energy, such as sunlight and the like, comprising a transparent polymer sheet having an edge and a surface, on which said electromagnetic radiation can impact, and a photovoltaic cell mechanically coupled with said edge of said polymer sheet, capable of transforming in an electrical current the radiation incident on it, characterized in that said polymer sheet comprises a polymeric matrix having silicon nanostructures, functionalized with organic binders, said polymeric sheet being then luminescent with respect to a portion of said electromagnetic radiation, so as to convey the same, through a wave-guide, towards said photovoltaic cell. Also disclosed is a method for realizing a polymeric matrix, for the manufacture of a transparent polymer sheet.

The present invention relates to a device and realization method of luminescent solar concentrators based on silicon nanostructures.

More specifically, the invention concerns a device of the above type, designed and manufactured in particular to convert solar energy into electrical energy in a transparent material, which can be used in architectural elements, such as windows and the like.

In the following the description will be directed to the use of said device in particular for windows, but it is clear that it should not be considered limited to this specific use.

As is well known, the search for cheap, abundant and renewable energy sources is one of the current most ambitious technological objectives.

Currently, the 85% of the total energy consumed on earth comes from fossil fuels, with the well-known consequences to global warming and to the human health.

Furthermore, the supply of fossil fuels is becoming increasingly expensive and difficult, as natural resources are progressively decreasing. In fact, it is expected that in 50-100 years these resources will by then be exhausted.

The search for alternative energy sources has therefore become a necessity.

Sunlight is the most economical, most evenly distributed, abundant and renewable energy source on the earth. The power of solar radiation that hits the surface of our planet is 10.000 times higher than the current global energy demand. In order to be usable, however, solar energy must be converted into forms that can be directly usable.

Although the systems based on solar cells (or Solar Cells) at low cost and high performance are currently very reliable, commercially available and widely developed, further advances in science and technology of solar cells need so as the photovoltaic to become the major source of energy and electricity in the world, so as to contribute to a significant extent to the generation of renewable electricity by 2020 (Horizon 2020).

One of the possibilities for converting solar energy into electricity currently studied is linked to the use of luminescent solar concentrators.

These devices are based on a polymeric or glass plate, inside (or on the surface) of which luminescent species are included capable of absorbing the incident light and re-emitting it at a specific wavelength within the solid matrix.

The incident light is then directed to the edges of the sheet, using internal total reflection processes. Placing in contact said edges of conventional solar cells having a good spectral overlap with the emitter included in the matrix, said light can be converted into electrical energy.

This device allows concentrating the light absorbed over a large area by a relatively low-cost material, on a series of small area photovoltaic cells.

This means, therefore, that high efficiency cells can be used, given the relative low cost of small dimension cells, keeping good overall efficiency levels and reduced costs.

Furthermore, this approach allows creating semi-transparent devices of remarkable interest for the integration of photovoltaic devices into architectural elements, such as windows or facades.

In this context, many emitters have been up to now used, starting from the common organic fluorophores to emitting nanomaterials.

The main limits of the emitters proposed up to now consist of:
a high light reabsorption, which limits considerably the efficiency of the concentrator;
a high degree of absorption in the visible spectrum, which limits its use as a transparent device;
a low stability in case of organic fluorophores;
a high intrinsic toxicity in case of lead and cadmium emitters;
a high synthesis complexity in case of multi-layer nanomaterials.

Solar energy conversion devices according to the prior art are also described in the international patent application WO2015/002995A1, in the article Meinardi, F.; McDaniel, H.; Carulli, F.; Colombo, A.; Velizhanin, K. A.; Makarov, N. S.; Simonutti, R.; Klimov, V. I.; Brovelli, S. Nat. Nanotechnol. 2015, 10 (10), 878-885, in the international patent application WO2016/060643A and in the international patent application WO2016/028855A.

In particular, the international patent application WO2016/060643 concerns a solar energy conversion device that uses different kinds of core-shell nanocrystals. For the operation of the device it is necessary, in particular, the presence of a core and a shell, both involved in the process of light absorption and emission.

The patent application WO2016/028855A1, moreover, concerns the functionalization of silicon nanocrystals with chromophoric ligands such as optical probes, which however increase the absorption properties of the material in the visible, an effect not required and even dangerous for the applications.

Consider, in particular, that it is known the application of quantum dots in polymeric matrices to which a solar cell is coupled. The advantage of this technology is to show a bandwidth (or “band-gap”) easily adjustable according to the size of said quantum dots. Recently, however, despite the good results in terms of efficiency, it was found that quantum dots present toxicity problems.

It is apparent that the solutions according to the prior art are not optimal in terms of technical performance and efficiency, and therefore still not usable for commercial purposes.

In light of the above, it is therefore an object of the present invention overcoming the technical limits of the currently known solar energy conversion devices.

It is also an object of the present invention to propose a solar energy conversion device made of non-toxic, non-rare, and highly transparent materials.

It is a further object of the present invention to propose a method for producing said solar energy conversion device.

It is specific object of the present invention an energy conversion device, particularly electromagnetic energy, such as sunlight and the like, comprising a transparent polymer sheet having an edge and a surface, on which said electromagnetic radiation can impact, and a photovoltaic cell mechanically coupled with said edge of said polymer sheet, capable of transforming in an electrical current the radiation incident on it, characterized in that said polymer sheet comprises a polymeric matrix having silicon nanostructures, functionalized with organic binders, said polymeric sheet being then luminescent with respect to a portion of said electromagnetic radiation, so as to convey the same, through a wave-guide, towards said photovoltaic cell.

Always according to the invention, said silicon nanostructures may comprise silicon nanocrystals (SiNCs) and/or silicon nanowires and/or porous silicon.

Still according to the invention, said silicon nanostructures may have a size smaller than, or equal to 100 nm.

Advantageously according to the invention, the organic binders may be selected from the group consisting of: linear alkyl or alkenyl binders, such as 1-dodecene, 1-decene, 1-hexadecene, 1-undecene, 1-octadecene; alkyl or alkenyl silicon-containing binders, such as chloro(dimethyl) vinylsilane, chloro(dimethyl) allylxylane, chloro(dipropyl) vinylsilane, chloro(dibenzyl) vinylsilane and derivatives of the same; ethylene glycols binders; aromatic binders, such as styrene, phenylacetylene, anthracene, naphthalene, 2-aminopyridine, quinine sulphate and derivatives of the same; said binder providing specific solubility, dispersion, stability or ultraviolet light absorption properties, said binders mixtures can be used to provide simultaneously different properties.

Further according to the invention, said polymeric matrix may be based on a functional monomer, such as lauryl methacrylate, methyl methacrylate, styrene or derivatives of the same; and a linking agent such as ethylene glycol dimethacrylate, propylene glycol methacrylate or derivatives.

Preferably according to the invention, the ratio between the functional monomer and the linking agent described above may be comprised between 5% and 30%.

It is further object of the present invention a method for realizing a polymeric matrix, for the manufacture of a transparent polymer sheet, having silicon nanostructures, comprising the following steps: (a) synthesize said silicon nanostructures by a thermal annealing step in a reducing atmosphere of polysiloxanes, for obtaining a powder; (b) treating said powder obtained in said synthesizing step (a) with hydrofluoric acid to remove the silicon oxide matrix and release said hydride terminated silicon nanostructures; and (c) functionalizing said silicon nanostructures by the reaction with an organic binder selected from the group consisting of chloro(dimethyl) vinylsilane, chloro(dimethyl) allylxylane, chloro(dipropyl) vinylsilane, chloro(dibenzyl) vinylsilane and derivatives of the same; ethylene glycols binders; aromatic binders, such as styrene, phenylacetylene, anthracene, naphthalene, 2-aminopyridine, quinine sulphate and derivatives of the same. Always according to the invention, said functionalizing step (c) may comprise the step of induced passivation by heating the silicon nanostructures in an inert atmosphere at temperatures greater than, or equal to 150° C., with an organic binder.

Still according to the invention, said functionalizing step (c) may comprise the passivation step induced by the activation of the silicon nanostructure by reaction with a diazonium salt, such as for example, 4-decylbenzene diazonium tetrafluoroborate, 4-bromobenzene diazonium tetrafluoroborate, 2-nitro-4-decyl-benzene diazonium tetrafluoroborate and 2,6-bromo-decyl-benzene diazonium tetrafluoroborate or AIBN (2,2′-azobis (2-methylpropionitrile) and subsequent addition of the organic binder in solvents such as toluene, hexane, cyclohexane, dichloromethane, chloroform, tetrahydrofuran.

Advantageoulsy according to the invention, in the passivation step it may be used a solvent selected from the same organic ligand or a neutral solvent selected from dodecane, hexadecane, octadecane, mesitylene, dichlorobenzene, trichlorobenzene, toluene, hexane, cyclohexane, dichloromethane, chloroform, tetrahydrofuran.

Further according to the invention, said method may further comprise the following step: (d) preparing said polymeric matrix, in which including said silicon nanostructures, within a polymer matrix by in-situ polymerization of the polymers of said matrix.

Preferably according to the invention, said in-situ polymerization step (d) may be carried out by dispersing said silicon nanostructures in a mixture of functional monomer and linking agent with a thermal or photochemical initiator.

Always according to the invention, said mixture of lauryl methacrylate/ethylene glycol dimethacrylate comprises lauryl methacrylate from 60% to 90% by weight and ethylene glycol dimethacrylate from 10 to 40% by weight.

Still according to the invention, said thermal initiator may be a solution of lauryl peroxide, AIBN (2,2′-azobis (2-methylpropionitrile, ABCN 1,1′-azobis (cyclohexanecarbonitrile) or benzoyl peroxide, in a concentration ranging from 0,05% to 1% by weight with respect to the solution.

Advantageously according to the invention, said photochemical initiator may be a solution of diphenyl (2, 4, 6-trimethylbenzoyl) phosphine oxide or Irgacure 651 in a concentration ranging from 0,05% to 1% by weight with respect to the solution.

Further according to the invention, said method may comprise a thermal activation phase, at a temperature between 40° C. and 100° C., and/or photochemistry activation phase, with irradiation in the range between 300 and 450 nm, of said polymerization of said mixture in an appropriate mold until reaching the solid state.

Preferably according to the invention, said method may comprise the step of removing the device from the mold and the following polishing of the surface by mechanical means.

Always according to the invention, said nanostructures may comprise silicon nanocrystals and/or nanowires of silicon and/or porous silicon.

The present invention will be now described, for illustrative but not limitative purposes, according to its preferred embodiments, with particular reference to the figures of the enclosed drawings, wherein:

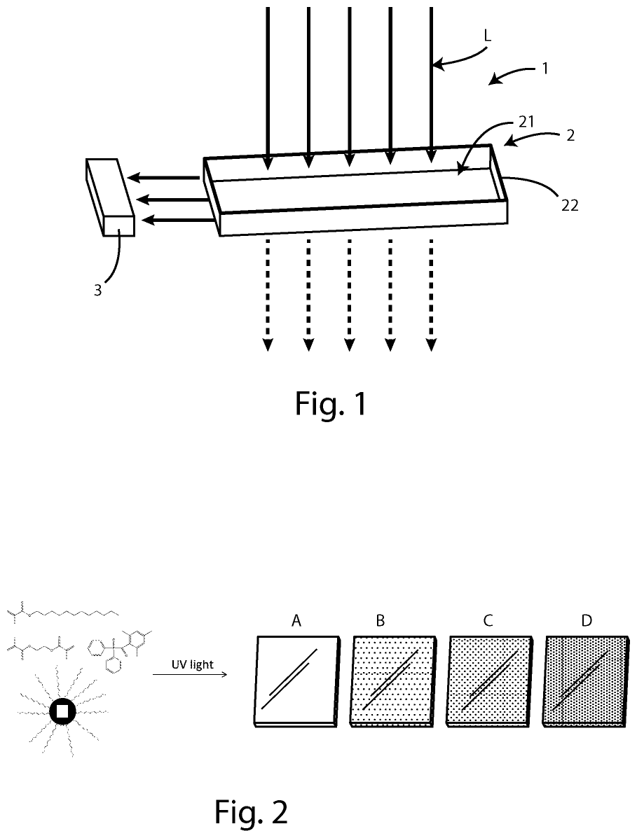

FIG. 1 shows a schematic view of the operating principle of a solar energy conversion device according to the present invention;

FIG. 2 shows the scheme of the polymerization process that leads to the transparent polymeric material with different percentages of silicon nanostructures (increasing percentage from left to right);

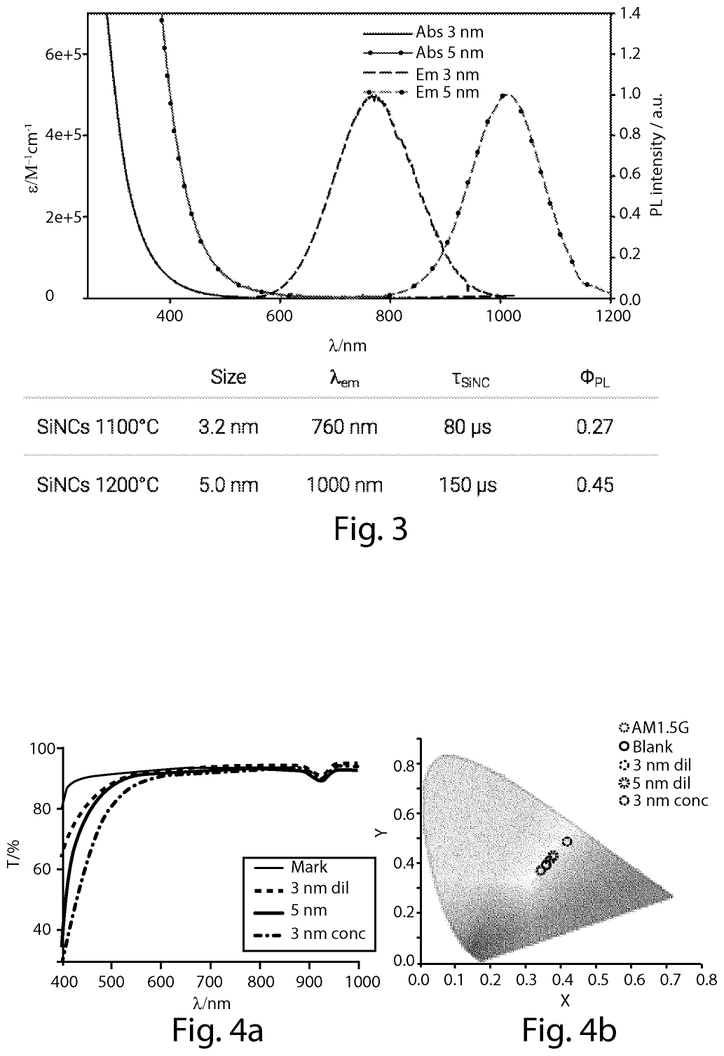

FIG. 3 shows a graph showing the photophysical properties of two experimental samples in a solution of toluene of a polymeric matrix made according to the present invention;

FIG. 4a shows the transmittance of visible and UV light of the four samples shown in FIG. 2;

FIG. 4b shows the chromaticity diagram of the four samples shown in FIG. 2;

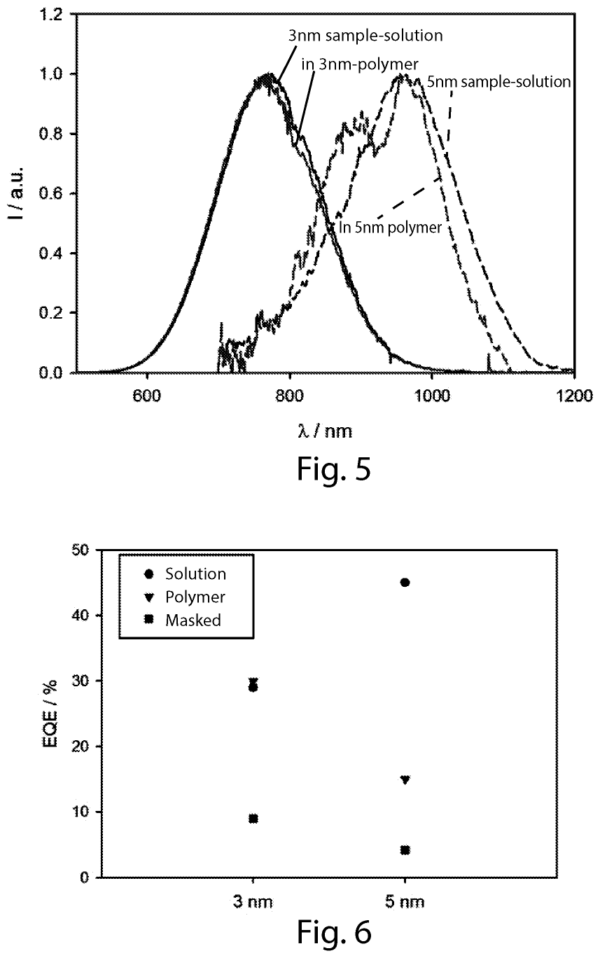

FIG. 5 shows normalized emission spectra of silicon nanocrystals SiNCs of different sizes (3 nm and 5 nm) in solution and in polymeric matrix;

FIG. 6 shows the external quantum efficiency (EQE) for some nanocrystals in solution or included in a polymeric matrix possibly with or without the masked edges;

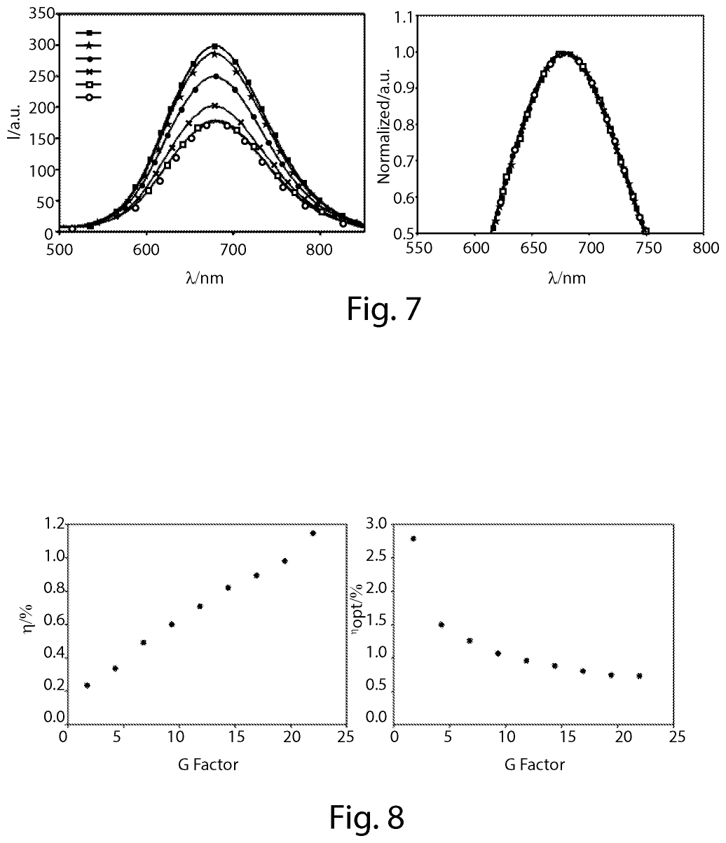

FIG. 7 shows emission spectra of a polymeric matrix with silicon nanocrystals detected at the greater distance between the excitation source and the emission point;

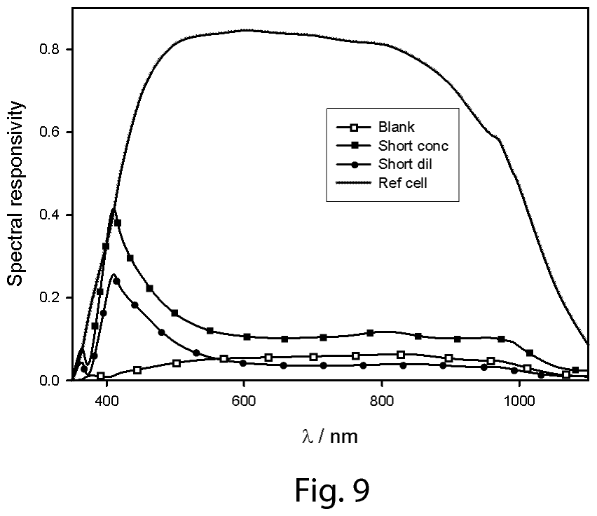

FIG. 8 shows the dependency of the efficiency of a photovoltaic cell and the optical efficiency with respect to the G factor; and

FIG. 9 shows the comparison between the spectral response of a photovoltaic cell illuminated perpendicular to the surface and that obtained for the photovoltaic cell coupled with polymeric plates with different concentrations of nanocrystals, or without nanocrystals.

In the various figures, similar parts will be indicated by the same reference numbers.

Referring to FIG. 1, a schematic functional view of a solar energy conversion device 1 according to the present invention is observed.

The device 1 comprises a transparent polymeric sheet 2 and at least one solar cell 3, placed on at least one portion of the edge 22 of the polymer sheet 2 and mechanically coupled to it, e.g. by a layer of transparent adhesive tape, in order to reduce the roughness of the polymer sheet 2 and to increase the optical quality.

Said polymer sheet 2 comprises nanostructures, in particular silicon nanocrystals SiNCs, functionalized with alkyl derivatives, which are luminescent in red or in the near infrared (NIR).

The nanostructures contained in the polymer sheet 2 are included by in-situ polymerization (see also FIG. 2), thermally or photochemically carried out by a UV source.

These nanostructures are generally silicon nanocrystals (also SiNcs), but they can also be silicon nanotubes, silicon nanowires or porous silicon. In the following, in any case, reference will be made to the use of SiNcs silicon nanocrystals, without this being a limitation of the scope of protection.

It is seen that the solar energy conversion device 1 shows a high simplicity of the encapsulation process of the nanomaterial in the matrix and compatibility with the polymerization process, as better defined below.

Silicon nanocrystals (SiNCs) have particular optical and electronic properties, as better discussed below, compared to those of massive silicon. These properties are mainly connected to quantum confinement effects and are therefore strongly dependent on the size, shape, surface functionalization of the nanocrystals and the presence of defects.

In general, silicon nanocrystals preferably have a size between 2-12 nm, thus showing a light emission that can be regulated form the visible spectrum region to the near infrared spectrum region, simply by increasing their size.

Moreover, silicon nanocrystals have different advantages with respect to known, more widespread and used quantum dots, which, as mentioned, generally contain rare and/or toxic materials such as lead, cadmium, indium, selenium.

FIG. 2 shows a synthesis of the diagram of the polymerization process for obtaining the transparent polymeric material with different percentages of silicon nanostructures (increasing percentage from left to right of the above figure, indicating the samples obtained with A (no nanostructure), B, C and D, which indicate different concentrations and dimensions of silicon nanocrystals SiNCs, as better explained below).

Among the advantages of silicon nanocrystals SiNCs, the following can be mentioned.

Preliminarily, silicon is abundant, readily available and essentially non-toxic. Furthermore, silicon can form covalent bonds with carbon, thus providing the possibility of integrating inorganic and organic components into a robust structure.

Moreover, as the size of silicon nanocrystals SiNCs varies, it is possible to control the absorption and the emission spectra, which can therefore cover the entire ultraviolet, visible and near infrared spectrum.

In the energy conversion device 1 according to the present invention, the silicon nanocrystals SiNCs are obtained as follows:
(a) they are synthesized by annealing (heat treatment) in a reducing atmosphere of polysiloxanes (inorganic polymers based on a silicon-oxygen chain and organic functional groups linked to silicon atoms);
(b) the powder obtained in the previous step is treated with hydrofluoric acid, to remove the silicon oxide matrix and release the hydride terminated silicon nanostructures;
(c) the nanocrystals are then functionalized with alkenyl derivatives, to obtain optimal optical properties for the application described (emission in the desired spectral region, quantum yield between 30 and 60%, lack of reabsorption) and guarantee the correct solubilization and stabilization of the nanocrystals inside of the polymer matrix.

The above functionalization step (c) can be obtained according to one of the following two methods:
passivation induced by heating the nanocrystal in an inert atmosphere at temperatures higher than 150° C. in the presence of alkenyl binder, in order to obtain the relative functionalization. One or more binders can be used, depending on the properties to be supplied to the nanocrystal, such as maintenance or optimization of the optical properties described above, stabilization with respect to aggregation, prevention of energy transfer between different crystals, chemical stability against oxidative processes. The functionalization can be carried out using the binder as solvent or in the presence of neutral and high-boiling solvent (dodecane, hexadecane, octadecane, mesitylene, dichlorobenzene, trichlorobenzene);
passivation induced by activation, by means of diazonium salt. In this case the passivation can take place at room temperature by the addition of a special diazonium salt (for example 4-decylbenzene diazonium tetrafluoroborate) and by the following addition of alkenyl binder. In this case, the presence of a high-boiling solvent (toluene, hexane, cyclohexane) is not necessary.

Such binders will have the role of providing specific solubility, dispersion, stability or ultraviolet light absorption properties. Mixtures of binders can be used to provide different properties at the same time.

As said, the obtained nanocrystals are included within a polymer or polymer matrix by in situ polymerization of a mixture of lauryl methacrylate/ethylene glycol dimethacrylate comprises lauryl methacrylate, 80% by weight of the mixture, and ethylene glycol dimethacrylate, 20% by weight of the mixture, in the presence of a thermal initiator (lauroyl peroxide 0.05-0.1% by weight with respect to the solution) or photochemical (diphenyl) (2,4,6-trimethylbenzoyl) phosphinide 0.05-0.1% by weight with respect to the solution).

Said nanocrystals maintain their luminescence properties within the polymeric matrix due to the protective function provided by the organic binder covalently bonded to the silicon core.

As anticipated, a new aspect of the solar energy conversion device 1 according to the invention concerns the use of silicon nanostructures functionalized with organic binders.

These offer optimal optical properties for the indicated applications, allowing:
an emission in a variable range of the light spectrum as the dimensions vary;
a high luminescent quantum performance; and
an absorption spectrum mainly positioned in the near UV region and high Stokes-shift (distance in energy between maximum absorption and light emission) that prevents effects of reabsorption of the emitted light, generally due to a remarkable decrease in the efficiency of this type of device.

Unlike other types of nanocrystals, silicon nanocrystals SiNCs have the advantage of being made of a single element, contrary, for example, to mixed semiconductors based on PbS, CdS, CdSe, CdTe, CulnSe etc..

The organic functionalization also allows modifying the optical, solubility, dispersion and stability properties.

In general, the optical performance of the polymer sheet 2, which actually acts as, and it is a luminescent solar concentrator (also Luminescent Solar Concentrator—LSC) is defined as the fraction of the incident photons L on said polymer sheet 2, which are re-emitted and capable of reaching the edges 22 and therefore the solar cell 3. The optical efficiency of said polymer sheet 2 is influenced by several factors, shown in the following equation:

ηₒₚₜ=(1−R)PTIRη_{abs}η_{PL}η_{Stokes}η_{wvg}η_{self}

wherein R is the reflection of the light incident on the polymer surface, which said polymer sheet 2 is constituted of, PTIR is the total internal reflection efficiency defined by Snell's law, η_{abs} is the fraction of light absorbed by the photoactive elements, η_{PL} is the photoluminescent quantum yield, η_{Stokes} is the energy lost due to the generation of heat from absorption-emission events, η_{wvg} is the transport efficiency of the photons emitted through the waveguide relative to the geometry and the smoothness of the surface of said polymer sheet 2, η_{self} is the transport efficiency due to reabsorption.

The two main contributions, in terms of loss probability, are the superficial losses described by R and η_{wvg}, and the reabsorption.

While the first problem can be addressed by the use of different configurations, such as the use of a cylindrical or semi-reflecting layers, the second is mainly related to the photophysics of the lumonophore (i.e., in the case at issue, of the silicon nanocrystal SiNCs).

The use of nanomaterials designed to achieve a Stokes-shift effect, such as silicon nanocrystals SiNCs, reduces considerably the losses due to re-absorption. In fact, silicon is an indirect band-gap semiconductor and, despite the photoluminescence quantum yield up to 45%, when the size is reduced at the level of nanostructures, it is characterized by a long duration of photoluminescence and high Stokes-shift, which is typical of transitions assisted by phonons.

The preparation of a test solar energy conversion device 1 according to the invention is described in detail below.

Two batches of silicon nanocrystals SiNCs passivated in dodecene are synthesized respectively preparing nanocrystals with an average diameter of about ˜3 nm and ˜5 nm.

The main photophysical properties of the samples in toluene solution are shown in FIG. 3. It can be seen that, by increasing the size of silicon nanocrystals SiNCs, the wavelength corresponding to the maximum photoluminescence intensity (Photoluminescence-PL) is shifted in order to lower the energy towards the near infrared NIR region (following a smaller band gap for larger nanocrystals).

As already highlighted, the photoluminescence in the microsecond interval confirms the nature of indirect band-gap of the material. Even the apparent Stokes-shift, corresponding to the energy gap between the end of the absorption tail and the beginning of the emission band, increases with the size of the silicon core.

The polymer test plates in which the silicon nanocrystals SiNCs are incorporated have been prepared by adapting a process described in the article of Coropceanu, I.; Bawendi, M. G. Nano Lett. 2014, 14 (7), 4097-4101, reducing the quantity of photoinitiator, in order to optimize the light component absorbed by silicon nanocrystals SiNCs: 300 ml of concentrated silicon nanocrystal SiNCs solution in toluene (˜10-4-10-3M depending on the batch) were carefully dried under vacuum.

Meanwhile, a solution of the monomeric precursor (LMA, lauroyl methacrylate, Sigma-Aldrich), cross-linking agent (EGDM, ethylene glycol dimethacrylate, Sigma-Aldrich, 20% w/w with respect to LMA) and a UV initiator (diphenyl (2), 4,6-trimethylbenzoyl) phosphinide oxide), Sigma-Aldrich, 0.1%) was prepared by sonication for 10 minutes.

The silicon nanocrystals SiNCs were then dissolved in 6 ml of monomer and the solution was degassed in 3 cycles of freezing-pumping-thawing, to prevent the formation of bubbles during polymerization. The solution was then placed in a mold consisting of two sheets of glass, separated by a silicone spacer and irradiated with a radiation having a wavelength λ_{exc}=365 nm for 1 hour.

The resulting polymer plate was left in the dark for 24 hours, to allow the completion of the polymerization. Then the mold was removed and the obtained polymer matrix was polished with abrasive paper and diamond paste (1 micron), in such a way as to limit the roughness of the surface of the device, improving the waveguide effect.

The photophysical characterizations of the test polymer matrix obtained above intended for the manufacture of the polymer sheet 2 of the conversion device 1 are examined below.

In particular, three examples of polymer matrix were prepared with silicon nanocrystals SiNCs with an average size of about 30×25×4 mm (refer again to FIG. 2), incorporating silicon nanocrystals SiNCs having the dimension of 3 nm at different concentrations (respectively 4×10⁻⁶ M for the sample B sample and 2×10⁻⁵ M for the sample D) or silicon nanocrystals SiNCs of 5 nm (sample C). A reference sample was also prepared without inserting any luminophore.

The sample transmission spectra are shown in FIG. 4a. Comparing the spectra in the low-energy region, no evidence of aggregation is observed and the average transmittance (800-600 nm) is higher than 94%, demonstrating the excellent degree of transparency of the prepared polymeric sheets or matrices.

The unstructured band at wavelengths lower than 500 nm is related to the absorption of silicon nanocrystals SiNCs.

The average transmittance was calculated in the visible region (400-800 nm) and the extracted values, shown in the table below, ranged from 92% of the blank sample, to 83% of the sample with silicon nanocrystals SiNCs of concentrated 3 nm size. This means that, in the worst case, silicon nanocrystals SiNCs absorb less than 10% of the incident light, so a high degree of transparency is maintained.

Since the average transmittance provides only limited information about the visual appearance of the semi-transparent plate, the color coordinates and the color rendering (CRI) have been calculated using the CIE 1931 chromaticity diagram, whose values are shown in the following table.

| | | | | | Colour |
|---|---|---|---|---|---|
| | | Average | | | Rrendering |
| | | transmittance % | x | y | Index |
| | AM 1.5 G | — | 0.3470 | 0.3694 | 95.70 |
| A | Blank | 92.1 | 0.3602 | 0.3921 | 91.71 |
| B | 3 nm dil | 89.3 | 0.3724 | 0.4106 | 88.96 |
| C | 5 nm dil | 87.3 | 0.3817 | 0.4269 | 85.79 |
| D | 3 nm conc | 83.4 | 0.4016 | 0.4557 | 80.14 |

It should be noted that the measure of AM 1.5 G is the standard solar irradiation (used to evaluate the efficiency of photovoltaic panels) through a thickness of 1,5 atmospheres, corresponding to solar irradiation with an angle at the zenith of 48.2°.

The color coordinates of the plates obtained are located in the central region of the chromaticity diagram shown in FIG. 4b, indicating good achromatic or neutral color perceptions. Only a small displacement to the yellow-orange region of the spectrum was detected for the concentrated sample with the silicon nanocrystal SiNCs at 3 nm.

Further indications about the color rendering have been provided by the calculation of the above mentioned CRI, whose value is between 91.71% for the blank sample, i.e. without silicon nanocrystals SiNCs, and 80.4% for the sample with the highest concentration of silicon nanocrystals SiNCs with crystal size of 3 nm. These values meet the CIE requirements for interior lighting.

The photoluminescence properties of silicon nanocrystals SiNCs embedded in the matrix were compared with those in the solution, starting from the form factor.

As is evident from FIG. 5, no particular variation of the band shape was observed for the sample having 3 nm silicon nanocrystals SiNCs, whereas the sample having 5 nm silicon nanocrystals SiNCs is characterized by a drastic change in the form of the band. This variation is due to the overlap of the emission band with the absorption bands of the polymer matrix.

The external quantum efficiency (also EQE) of silicon nanocrystals SiNCs, once incorporated into the polymer matrix, was evaluated and compared with the quantum photoluminescence yield of the same nanocrystals dissolved in toluene.

Firstly, the quantum yield measurement was performed on silicon nanocrystals SiNCs of 3 SiNCs nm and 5 nm in toluene solution.

For the evaluation of the EQE of silicon nanocrystals SiNCs embedded in the polymer matrix, a 3×2 cm support for the plates was constructed and a reference plate was prepared without the addition of silicon nanocrystals SiNCs. While, for the 3 nm silicon nanocrystals SiNCs sample, the EQE was observed to be relatively similar to that of the sample in solution, about 30%, the 5 nm silicon nanocrystals SiNCs sample is affected by a drastic decrease in the EQE up to 15%, due to the reabsorption of the polymer matrix.

In order to obtain information on the optical efficiency of the polymer sheet 2, the EQE of the silicon nanocrystals SiNCs embedded in the polymer sheet 2 itself was measured and compared with the EQE of the same polymer sheet 2 with edges masked (subtracting the contribution of the edges for the quantum efficiency). In particular, the edges of the sample were masked with 3 nm silicon nanocrystals SiNCs.

A decrease of the EQE from 30% to 9% has been observed (refer to the squares in FIG. 6), which indicates that 68% of the contribution to the overall emissions intensity comes from the edges of the polymer sheet 2, thus revealing that there are few losses due to reabsorption or reflection surface.

The same phenomenon was observed for the sample having silicon nanocrystals SiNCs of 5 nm, although the absolute values decrease from an EQE much lower than 15% to less than 4%.

This reduced efficiency is related to the lower quantum yield of the nanocrystals due to the polymer reabsorption.

This still implies a limitation on the use of luminophores emitting in the NIR (Near Infra-Red) region, i.e. 900-1100 nm, in the presence of a methacrylate matrix. Finally, to show the lack of re-absorption of the light emitted by silicon nanocrystals SiNCs, the luminescence was measured as a function of the distance between the excitation point and the radiation collection edge.

As shown in FIG. 7, the luminescence intensity decreases, as expected, due to optical losses and the geometric factor between the detector collecting angle and the emission cone, but no variation of the band shape was observed, indicating that there is no reabsorption.

The photovoltaic performance of the polymer sheet 2 according to the invention was evaluated by placing a photovoltaic cell 3 on the top of an edge of the plate, and measuring the efficiency of the cell radiating perpendicularly the plate surface with a conventional AM 1.5G solar simulator.

Measurements were made by leaving the edges 21 free from contact with any material, and by masking them with an aluminum sheet to make a mirror or by masking them with a specific black tape, capable of absorbing the light emitted from the edges in the whole visible and infrared spectrum.

The form factor, called G factor and defined as the ratio between the surface of the upper part of the polymer sheet 2 and the surface of the edges 21, has been calculated taking into consideration only the edge in contact with the photovoltaic cell 3 by placing mirrors on the other edges.

When no mirror was used during the measurement, the G factor was calculated considering the surface of all the edges 21 as active surface.

The optical contact between the photovoltaic cell 3 and the polymer sheet 2 has been optimized by adding a layer of transparent adhesive tape, in order to reduce the roughness of the face 22 of the polymer sheet 2 and to increase the optical quality of the interface with the solar cell 3.

Further polymer sheets 2 were prepared, having 3 nm silicon nanocrystals SiNs, changing the size of the plates themselves.

The size and composition of the samples is described in the following table, in analogy with the samples previously prepared for the physical photo characterization. The same table also shows the JV characteristics, i.e. the current-voltage density, together with the previously described G factor and the light fraction absorbed by the sample, calculated by integrating the absorption spectrum on the 1.5G AM spectrum.

| | | | | Jsc/ | | | | | □quantum/ |
|---|---|---|---|---|---|---|---|---|---|
| | Size/mm | G | □abs | mA/cm2 | Voc/V | FF/% | PCE/% | □opt/% | % |
| Blank | 23 × 22 × 3.9 | 1.00 | — | 2.2 | 0.393 | 0.53 | 0.48 | 7.0% | — |
| | | 1.00 | | 0.9 | 0.330 | 0.53 | 0.17 | 3.0% | |
| | | (black) | | (black) | (black) | (black) | (black) | (black) | |
| | | 5.92 | | 2.4 | 0.391 | 0.53 | 0.49 | 1.0% | |
| | | (mir) | | (mir) | (mir) | (mir) | (mir) | (mir) | |
| Small | 24 × 23 × 3.9 | 1.04 | 6.0% | 3.3 | 0.426 | 0.53 | 0.74 | 10.5% | 176.0% |
| dil | | 1.04 | | 1.5 | 0.414 | 0.52 | 0.28 | 9.3% | 155.1% |
| | | (black) | | (black) | (black) | (black) | (black) | (black) | (black) |
| | | 6.32 | | 3.6 | 0.432 | 0.51 | 0.80 | 1.9% | 31.9% (mir) |
| | | (mir) | | (mir) | (mir) | (mir) | (mir) | (mir) | |
| Small | 32 × 23 × 3.8 | 1.17 | 9.0% | 5.5 | 0.462 | 0.54 | 1.40% | 16.7% | 184.6% |
| conc | | 1.17 | | 4.07 | 0.454 | 0.55 | 1.05% | 12.0 | 126.5% |
| | | (black) | | (black) | (black) | (black) | (black) | (black) | (black) |
| | | 8.01 | | 6.1 | | 0.55 | 1.62% | 2.6% | 28.8% (mir) |
| | | (mir) | | (mir) | | (mir) | | (mir) | |
| Long | 87 × 16 × 3.9 | 1.33 | 7.5% | 4.17 | 0.4193 | 0.52 | 0.95% | 10.8% | 144.1% |
| dil | | 1.33 | | 4.7 | | 0.52 | 0.87% | 9.2% | 122.8% |
| | | (black) | | (mir) | | (mir) | (black) | (black) | (black) |
| | | 21.9 | | | | | 1.15% | 0.8% | 8.8% (mir) |
| | | (mir) | | | | | (mir) | (mir) | |

For calculating the short circuit current density, indicated with J_{sc}, the area of the concentrator physically in contact with the cell surface, equal to 0.48 cm², has been considered. We note that the power conversion efficiency (as mentioned, also Power Conversion Efficiency—PCE) is strongly enhanced by the presence of silicon nanocrystals SiNCs with respect to the polymer plate without any luminophore, ranging from 40% to 330% of the growth factor. This improvement is due to an increase in the short circuit current (J_{sc}), which is directly proportional to the flow of incident photons.

Since the open circuit voltage (V_{oc}) and the filling factor (FF) are only slightly dependent on the flow of photons, these last parameters have not been particularly influenced by the presence of silicon nanocrystals SiNCs. It is also possible to note that no particular increase in efficiency has been observed by mirroring the surface of the free edges (i.e. addition of reflecting surfaces or mirrors on the edges).

To obtain information on the concentration efficiency of the polymer sheet 2, the optical yield from the photovoltaic measurements was calculated with the following formula:

$${η}_{opt} = \frac{{J}_{LSC}}{{J}_{SC} \times G}$$

Where J_{LSC} is the current density of the photovoltaic cell 3 coupled with the polymer sheet 2, J_{SC} is the current density of the photovoltaic cell 3 under a direct illumination and G is the dimensional factor described above. Likewise the PCE, optical efficiency is also greatly improved by the presence of silicon nanocrystals SiNCs.

For measurement with reflecting surfaces, ηₒₚₜ moves from 0.1% for the sample without nanocrystals, to 2.6%, in case of a sample with high concentration of silicon nanocrystals SiNCs.

The same behavior can be observed for the measurements with the reflecting surfaces on the edges 21, but the absolute values are considerably increased up to 16.7%. This difference can be attributed to the lowest G factor, calculated for this measurement configuration, which is probably overestimated.

In fact, this measurement configuration takes into account that the light which strikes the edges 21 of the polymer sheet 2 not coupled with the photovoltaic cell 3 is entirely dispersed, although in a more realistic case the diffusion from such edges can not be neglected. This radiation probably contributes to the overall efficiency of the polymer sheet 2. For this reason, the measurements carried out in the configuration with the black tape show a lower and more accurate optical efficiency.

On the contrary, it is also expected that the configuration with the reflecting surfaces underestimate the real efficiency, since it involves more reflection events inside the polymer sheet 2, increasing the losses and reducing the overall optical efficiency.

This is also the reason for explaining why the Power Conversion Efficiency (PCE) measured with configurations with and without reflective surfaces is comparable.

The optical efficiency is dependent on the absorbed light fraction, so the optical quantum efficiency can be calculated just by dividing the optical efficiency by the light fraction absorbed by the polymer sheet 2:

$${η}_{opt} = \frac{{J}_{LSC}}{{J}_{SC} \times G \times {η}_{abs}}$$

Referring to FIG. 8, the dependence of the efficiency of the photovoltaic cell 3 and the optical efficiency with respect to the G factor for the sample with surfaces reflecting at the edges 21 with respect to the high concentration sample is shown, to get an information on the intrinsic limit of the optical efficiency in a sample with the dimensions of a real window.

It is observed that the efficiency of the photovoltaic cell 3 increases with a linear trend with the increase in the length of the side of the polymer sheet 2, in line with the increasing surface of the irradiated side. On the contrary, optical efficiency was observed to be exponentially decreasing with the increasing G-factor.

Interestingly, optical efficiency seems to stabilize when the G factor is greater than 15 to a value close to 0.8%, indicating that optical losses appear to be constant after a short distance due to lack of reabsorption.

Finally, the spectral response of the polymer sheet 2 was also measured, comparing it with that of the photovoltaic cell 2.

Comparing the shape of the spectral response between a polymer sheet 2 which incorporates silicon nanocrystals SiNCs and that of the free sample, a new band is clearly visible in the blue region (see FIG. 9), reproducing the absorption band typical of silicon nanocrystals SiNCs.

In general, the operation of the solar energy conversion device 1 described above is as follows.

When light L, or radiation in general, which in this case is sunlight, incides the surface 21 of said polymer sheet 2, the ultraviolet component and a small percentage of visible light are absorbed by silicon nanocrystals (SiNCs), which are then able to re-emit light C in the red or in the near infrared (NIR) inside the polymer, which said polymer sheet 2 is made of.

By means of a waveguide effect, the emitted light C is conveyed towards the edges 22 of the polymer sheet 2, where it is converted into electrical energy by said solar cell 3, thus generating a usable electric current.

An advantage of the solar energy conversion device according to the present invention is the low toxicity of the material used and the ease of production of the photoactive material.

A further advantage according to the present invention is given by the high availability of silicon in the terrestrial crust.

It is also advantage of the present invention the possibility of functionalizing the semiconductor with organic binders to modify the optical, solubility, dispersion, and stability properties.

The present invention has been described for illustrative but not limitative purposes, according to its preferred embodiments, but it is to be understood that modifications and/or changes can be introduced by those skilled in the art without departing from the relevant scope as defined in the enclosed claims.

1. An energy conversion device, particularly electromagnetic energy, such as sunlight and the like, comprising:
a transparent polymer sheet having an edge and a surface on which electromagnetic radiation can impact, and a photovoltaic cell mechanically coupled with said edge of said polymer sheet, capable of transforming in an electrical current the radiation incident on it, wherein said polymer sheet comprises a polymeric matrix having silicon nanostructures, functionalized with organic binders, said polymeric sheet being then luminescent with respect to a portion of said electromagnetic radiation, so as to convey the same, through a wave-guide, towards said photovoltaic cell.

2. The energy conversion device according to claim 1, wherein said silicon nanostructures comprise silicon nanocrystals (SiNCs) and/or silicon nanowires and/or porous silicon.

3. The energy conversion device according to claim 2, wherein said silicon nanostructures have a size smaller than, or equal to 100 nm.

4. The energy conversion device according to claim 1, wherein the organic binders are selected from the group consisting of: linear alkyl or alkenyl binders; alkyl or alkenyl silicon-containing binders; ethylene glycols binders; aromatic binders; wherein said organic binders provide specific solubility, dispersion, stability or ultraviolet light absorption properties, and wherein mixtures of the organic binders can be used to provide simultaneously different properties.

5. The energy conversion device according to claim 1, wherein said polymeric matrix is based on a functional monomer; and a linking agent.

6. The energy conversion device according to claim 5, wherein the ratio between the functional monomer and the linking agent is between 5% and 30%.

7. A Method for realizing a polymeric matrix, for the manufacture of a transparent polymer sheet, having silicon nanostructures, comprising:
synthesizing said silicon nanostructures by a thermal annealing step in a reducing atmosphere of polysiloxanes, thereby obtaining a powder;
treating said powder obtained by said synthesizing with hydrofluoric acid to remove the silicon oxide matrix and releasing said hydride terminated silicon nano structures; and
functionalizing said silicon nanostructures by a reaction with an organic binder selected from the group consisting of chloro(dimethyl) vinylsilane, chloro(dimethyl) allylxylane, chloro(dipropyl) vinylsilane, chloro(dibenzyl) vinylsilane and derivatives of the same; ethylene glycols binders; and an aromatic binder.

8. The method according to claim 7, wherein said functionalizing-comprises induced passivation by heating the silicon nanostructures in an inert atmosphere at temperatures greater than, or equal to 150° C., with an organic binder.

9. The method according to claim 8, wherein said functionalizing comprises the passivation induced by the activation of the silicon nanostructure by reaction with a diazonium salt and subsequent addition of the organic binder in a solvent.

10. The method according to claim 8, wherein the passivation comprises using a neutral solvent selected from the group consisting of dodecane, hexadecane, octadecane, mesitylene, dichlorobenzene, trichlorobenzene, toluene, hexane, cyclohexane, dichloromethane, chloroform and tetrahydrofuran.

11. The method according to claim 7, further comprising:
preparing a polymeric matrix, wherein said silicon nanostructures are incorporated within the polymeric matrix by in-situ polymerization of said matrix.

12. The method according to claim 11, wherein said in-situ polymerization is carried out by dispersing said silicon nanostructures in a mixture of functional monomer and linking agent with a thermal or photochemical initiator.

13. The method according to claim 12, wherein the polymeric matrix is prepared from a mixture of lauryl methacrylate/ethylene glycol dimethacrylate functional monomers comprising lauryl methacrylate from 60% to 90% by weight and ethylene glycol dimethacrylate from 10 to 40% by weight.

14. The method according to claim 12, wherein said thermal initiator comprises a solution of lauryl peroxide, AIBN (2,2′-azobis (2-methylpropionitrile, ABCN 1,1′-azobis (cyclohexanecarbonitrile) or benzoyl peroxide, in a concentration ranging from 0.05% to 1% by weight with respect to the solution.

15. The method according to claim 12, wherein said photochemical initiator comprises a solution of diphenyl (2,4,6-trimethylbenzoyl) phosphine oxide or Irgacure 651 in a concentration ranging from 0.05% to 1% by weight with respect to the solution.

16. The method according to claim 11, further comprising a thermal activation phase, at a temperature between 40° C. and 100° C., and/or photochemistry activation phase, with irradiation in the range between 300 and 450 nm, of said polymerization of said mixture in a mold until reaching the solid state.

17. The method according to claim 16, further comprising removing the device from the mold and mechanically polishing the surface.

18. The method according to claim 7, wherein said nanostructures comprise silicon nanocrystals, nanowires of silicon, and/or porous silicon.

19. The energy conversion device according to claim 4, wherein the linear alkyl or alkenyl binders are selected from the group consisting of 1-dodecene, 1-decene, 1-hexadecene, 1-undecene and 1-octadecene.

20. The energy conversion device according to claim 4, wherein the alkyl or alkenyl silicon-containing binders are selected from the group consisting of chloro(dimethyl) vinylsilane, chloro(dimethyl) allylxylane, chloro(dipropyl) vinylsilane, chloro(dibenzyl) vinylsilane and derivatives of the same.

21. The energy conversion device according to claim 4, wherein the aromatic binders are selected from the group consisting of styrene, phenylacetylene, anthracene, naphthalene, 2-aminopyridine, quinine sulphate and derivatives of the same.

22. The energy conversion device of claim 5, wherein the functional monomer is selected from the group consisting of lauryl methacrylate, methyl methacrylate, styrene and derivatives of the same.

23. The energy conversion device of claim 5, wherein the linking agent is selected from the group consisting of ethylene glycol dimethacrylate, propylene glycol methacrylate and derivatives thereof.

24. The method according to claim 7, wherein the aromatic binder is selected from the group consisting of styrene, phenylacetylene, anthracene, naphthalene, 2-aminopyridine, quinine sulphate and derivatives of the same.

25. The method according to claim 9, wherein the diazonium salt is selected from the group consisting of 4-decylbenzene diazonium tetrafluoroborate, 4-bromobenzene diazonium tetrafluoroborate, 2-nitro-4-decyl-benzene diazonium tetrafluoroborate, 2,6-bromo-decyl-benzene diazonium tetrafluoroborate and MEN (2,2′-azobis (2-methylpropionitrile).

26. The method according to claim 9, wherein the solvent is selected from the group consisting of toluene, hexane, cyclohexane, dichloromethane, chloroform and tetrahydrofuran.
